(19) United States
(12) Patent Application Publication
(10) Pub. No.: US 2016/0126933 A1
(43) Pub. Date: May 5, 2016

(54) FINITE IMPULSE RESPONSE FILTER AND FILTERING METHOD

(71) Applicant: Industrial Technology Research Institute, Hsinchu (TW)

(72) Inventors: Ming-Ho Lu, Yunlin County (TW); Chi-Tien Sun, Hsinchu City (TW)

(21) Appl. No.: 14/598,242

(22) Filed: Jan. 16, 2015

(30) Foreign Application Priority Data
Oct. 30, 2014 (TW) 103137590

(51) Int. Cl. H03H 17/02

(52) U.S. Cl. CPC H03H 17/0248

(57) ABSTRACT

A finite impulse response (FIR) filter and a corresponding filtering method are provided. The FIR filter receives an input sequence. The input sequence includes a plurality of input values. The FIR filter includes at least one first adder, at least one multiplier, and a second adder. Each first adder performs multiple addition operations simultaneously in parallel. Each addition operation outputs a sum of two of the input values. Each multiplier performs multiple multiplication operations simultaneously in parallel. Each multiplication operation outputs a product of one of the sums and one of a plurality of coefficients of the FIR filter. The second adder outputs a total sum of the products.

### CROSS-REFERENCE TO RELATED APPLICATION

This application claims the priority benefit of Taiwan application serial no. 103137590, filed on Oct. 30, 2014. The entirety of the above-mentioned patent application is hereby incorporated by reference herein and made a part of this specification.

### TECHNICAL FIELD

The present disclosure relates to a parallel finite impulse response (FIR) filter and a corresponding filtering method.

### BACKGROUND

A finite impulse response filter is usually used by a transmitter of a wireless communication system, and configured to shape a spectrum of a signal can pending for transmission, so that the signal match a spectrum mask desired by the specification.

In recent years, with developments of communication technologies starting form the wireless local area network (WLAN) through the fourth generation (4G) technology to the upcoming fifth generation (5G) technology, the communication technologies have become more complex and diverse. Accordingly, issues of the communication system such as power consumption, transport speed, and hardware area will receive more attentions.

### SUMMARY

The present disclosure is directed to a finite impulse response filter and a corresponding filtering method, which are capable of reducing power consumption and hardware area for a communication system while increasing a throughput of the communication system.

The finite impulse response filter of the present disclosure receives an input sequence. The input sequence includes a plurality of input values. The finite impulse response filter includes at least one first adder, at least one multiplier, and a second adder. Each of the at least one first adder performs a plurality of addition operations simultaneously in parallel. Each of the addition operations outputs a sum of two of the input values. The multiplier is coupled to the first adder. Each of the at least one multiplier performs a plurality of multiplication operations simultaneously in parallel. Each of the multiplication operations outputs a product of one of the sums and one of a plurality of coefficients of the finite impulse response filter. The second adder is coupled to the multiplier, and outputs a total sum of the products.

The filtering method of the present disclosure include the following steps: receiving an input sequence, wherein the input sequence comprises a plurality of input values; in each clock cycle of a plurality of clock cycles, performing a plurality of addition operations simultaneously in parallel, wherein each of the addition operations outputs a sum of two of the input values; in each of the clock cycles, performing a plurality of multiplication operations simultaneously in parallel, wherein each of the multiplication operations outputs a product of one of the sums and one of a plurality of coefficients; and outputting a total sum of the products.

The finite impulse response filter and the filtering method as described above are capable of reducing power consumption while increasing the throughput by a parallel architecture. The power consumption may be further reduced by disabling a part of the multiplication operations and the hardware area may be reduced by simplifying the multiplication operations.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a finite impulse response filter according to an embodiment of the present disclosure.

FIG. 2 is a schematic diagram illustrating a part of a multiplier according to an embodiment of the present disclosure.

FIG. 3 is a schematic diagram illustrating a part of a multiplier according to another embodiment of the present disclosure.

FIG. 4 is a schematic diagram illustrating transmission spectrum masks of the 802.11p communication standard.

FIG. 5 to FIG. 7 are schematic diagrams illustrating a plurality of finite impulse response filters according to an embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A finite impulse response filter (hereinafter, referred to as the FIR filter) may be expressed as a formula (1) below.

$$y ( n ) = {\sum }_{i = 0}^{N - 1} h ( i ) x ( n - i ) \qquad ( 1 )$$

In the formula (1), x(n) represents input values of the FIR filter, y(n) represents output values of the FIR filter, the value of n ranges from 0 to infinity, h(i) are coefficients of the FIR filter, and N is the number of h(i). The output values y(n) are convolutions of the input values x(n) to x(n−(N−1)) and the coefficients h(0) to h(N−1).

The coefficients h(i) of the FIR filter are symmetric, which means that the coefficients h(i) conform to a formula (2) below. According to the formula (2), the formula (1) may be simplified to obtain a formula (3) below.

$$\begin{matrix}h ( i ) = h ( N - 1 - i ) & ( 2 ) \\ y ( n ) = \{ {\sum }_{i = 0}^{( N - 3 ) / 2} h ( i ) [ x ( n - i ) + x ( n - ( N - 1 ) + i ) ] \} + h ( ( N - 1 ) \text{/} 2 ) x ( n - ( N - 1 ) \text{/} 2 ) & ( 3 )\end{matrix}$$

In the formula (3) above, it is assumed that N is an odd number. If N is an even number, the formula (3) should be replaced with a formula (4) below.

$$y ( n ) = {\sum }_{i = 0}^{N / 2 - 1} h ( i ) [ x ( n - i ) + x ( n - ( N - 1 ) + i ) ] \qquad ( 4 )$$

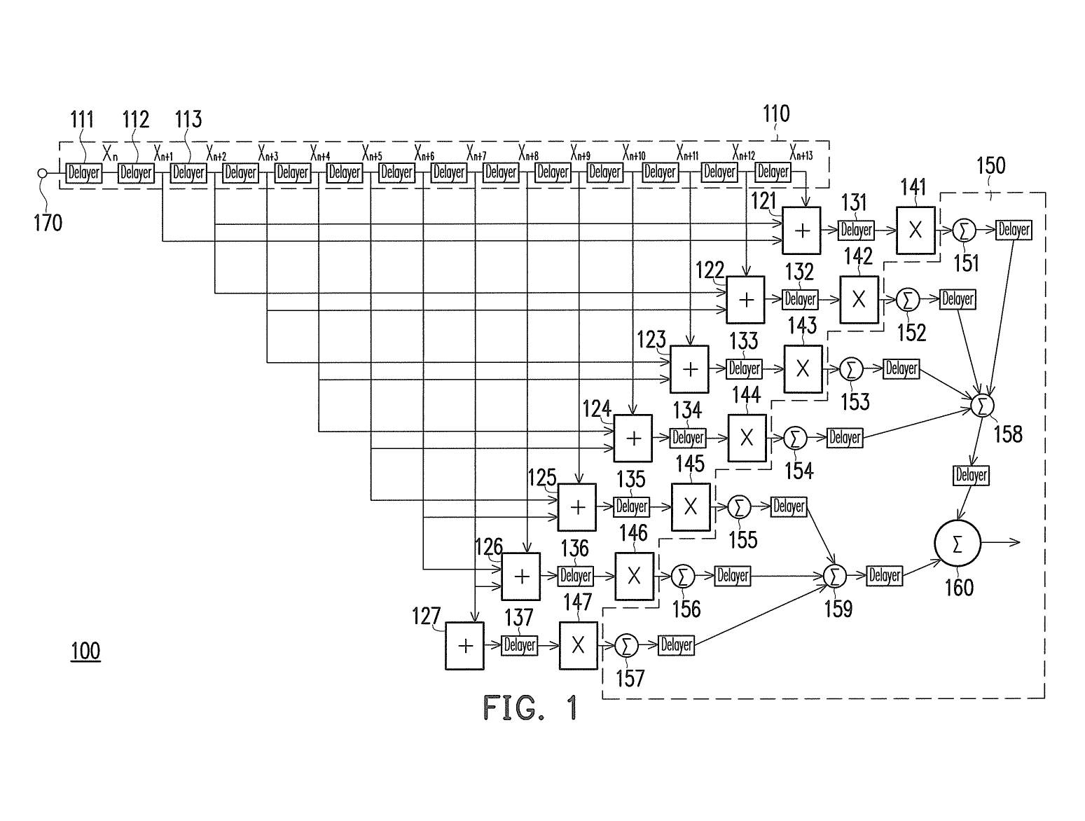

FIG. 1 is a schematic diagram illustrating a FIR filter 100 according to an embodiment of the present disclosure. The FIR filter 100 is a physical digital circuit designed according to the formula (3). The FIR filter 100 adopts a 4-way parallel architecture and includes 51 coefficients (i.e., N is equal to 51). The FIR filter 100 receives an input sequence from an input terminal 170, and the input sequence includes a plurality of input values. The FIR filter 100 includes a delay chain 110, adders 121 to 127, delayers 131 to 137, multipliers 141 to 147 and an adder 150. The adders 121 to 127 are coupled to the delay chain 110. The delayers 131 to 137 are coupled to the adders 121 to 127, respectively. The multipliers 141 to 147 are coupled to the delayers 131 to 137, respectively. The adder 150 is coupled to the multipliers 141 to 147.

The delay chain 110 receives the input sequence, and groups the input values into a plurality of batches Xₙ to Xₙ+13 according to the input order of the input values, in which each of the batches includes 4 input values. For instance, the 4 input values of the batch Xₙ₊₁ are represented by X_{n+1,1}, X_{n+1,2}, X_{n+1,3} and X_{n+1,4}, and the other input values may be deduced by analogy. The delay chain 110 may include at least one delayer coupled in series, such as delayers 111 to 113. Among the delayers of the delay chain 110, the first delayer receives the batches Xₙ to Xₙ+13 one by one directly from the input sequence. Each of the remaining delayers receives the batches Xₙ to Xₙ+13 one by one from the previous delayer. Each of the delayers delays the received batches for a predetermined time and then outputs the delayed bathes. The predetermined time may be one cycle of one clock signal. Each of the delayers of the FIR filter 100 may receive the clock signal as a basis for the delay.

Each of the adders 121 to 127 performs a plurality of addition operations simultaneously in parallel, and each of the addition operations outputs a sum of two of the input values in the input sequence. Each of the adders 121 to 127 directly obtains the input values from the batches outputted by the delayers of the delay chain 110. Each of the multipliers 141 to 147 performs a plurality of multiplication operations simultaneously in parallel, and each of the multiplication operations outputs a product of one of the sums and one of a plurality of coefficients of the FIR filter 100. Table 1 below lists the addition operations performed by the adders 121 to 127 and the multiplication operations performed by the multipliers 141 to 147.

TABLE 1

| | Addition | | Multiplication |
|---|---|---|---|
| Adders | operations | Multipliers | operations |
| 121 | X_{n+13,1} + X_{n+1,3} | 141 | s_{n,1} * h₁ |
| | X_{n+13,2} + X_{n+1,2} | | s_{n,2} * h₂ |
| | X_{n+13,3} + X_{n+1,1} | | s_{n,3} * h₃ |
| | X_{n+13,4} + X_{n+2,4} | | s_{n,4} * h₄ |
| 122 | X_{n+12,1} + X_{n+2,3} | 142 | s_{n,5} * h₅ |
| | X_{n+12,2} + X_{n+2,2} | | s_{n,6} * h₆ |
| | X_{n+12,3} + X_{n+2,1} | | s_{n,7} * h₇ |
| | X_{n+12,4} + X_{n+3,4} | | s_{n,8} * h₈ |
| 123 | X_{n+11,1} + X_{n+3,3} | 143 | s_{n,9} * h₉ |
| | X_{n+11,2} + X_{n+3,2} | | s_{n,10} * h₁₀ |
| | X_{n+11,3} + X_{n+3,1} | | s_{n,11} * h₁₁ |
| | X_{n+11,4} + X_{n+4,4} | | s_{n,12} * h₁₂ |
| 124 | X_{n+10,1} + X_{n+4,3} | 144 | s_{n,13} * h₁₃ |
| | X_{n+10,2} + X_{n+4,2} | | s_{n,14} * h₁₄ |
| | X_{n+10,3} + X_{n+4,1} | | s_{n,15} * h₁₅ |
| | X_{n+10,4} + X_{n+5,4} | | s_{n,16} * h₁₆ |
| 125 | X_{n+9,1} + X_{n+5,3} | 145 | s_{n,17} * h₁₇ |
| | X_{n+9,2} + X_{n+5,2} | | s_{n,18} * h₁₈ |
| | X_{n+9,3} + X_{n+5,1} | | s_{n,19} * h₁₉ |
| | X_{n+9,4} + X_{n+6,4} | | s_{n,20} * h₂₀ |
| 126 | X_{n+8,1} + X_{n+6,3} | 146 | s_{n,21} * h₂₁ |
| | X_{n+8,2} + X_{n+6,2} | | s_{n,22} * h₂₂ |
| | X_{n+8,3} + X_{n+6,1} | | s_{n,23} * h₂₃ |
| | X_{n+8,4} + X_{n+7,4} | | s_{n,24} * h₂₄ |
| 127 | X_{n+7,1} + X_{n+7,3} | 147 | s_{n,25} * h₂₅ |
| | X_{n+7,2} + 0 | | s_{n,26} * h₂₆ |

In the addition operations of Table 1, operands X_{n+1,3} to X_{n+13,1} are equivalent to the input values x(n) to x(n−(N−1)) in the formula (3). Each of s_{n,1} to S_{n,26} is the sum generated by the addition operation at the same row. For example, S_{n,24}=X_{n+8,4}+X_{n+7,4}) and the rest may be deduced by analogy. h₁ to h₂₆ are equivalent to the coefficients h(i) in the formula (3).

In view of Table 1, each of the adders 121 to 127 may perform at most four addition operations simultaneously. Each of the multipliers 141 to 147 may perform at most four multiplication operations simultaneously. The input value X_{n+7,2} is a midpoint of the entire input sequence. For each of the addition operations, the two of the input values for generating the sum are respectively before the midpoint of the input sequence and after the midpoint, and locations of the two of the input values in the input sequence are symmetric with respect to the midpoint X_{n+7,2}. If the number of the coefficients of the FIR filter 100 is an even number, the midpoint of the input sequence falls between two input values at the most middle. A symmetric relation of aforesaid locations of the input values can be observed in view of the formulas (3 and (4). Further, it view of Table 1, each of the adders 121 to 127 uses two groups of consecutive input values in the input values to perform the addition operations simultaneously. For example, a first group of the consecutive input values used by the adder 125 includes X_{n+9,1} to X_{n+9,4}, whereas a second group of the consecutive input values includes X_{n+5,3} to X_{n+6,4}.

The delayers 131 to 137 serve to allow each of the adders 121 to 127 and the corresponding multipliers 141 to 147 to operate in different clock cycles. For example, the adder 123 calculates the four sums s_{n,9} to s_{n,12} simultaneously in parallel in one specific clock cycle. Then, after the four sums are delayed by the delayer 133, the adder 143 obtains said four sums s_{n,9} to s_{n,12}, so as to perform four multiplication operations simultaneously.

The adder 150 includes a plurality of adders 151 to 160 and a plurality of delayers. The adder 151 calculates a sum of four products generated by the multiplier 141 in parallel and then outputs the sum. The adder 152 calculates a sum of four products generated by the multiplier 141 in parallel before outputting the sum, and the rest may be deduced by analogy. The adder 158 calculates a sum of output values of the adders 151 to 154 and then output the sum. The adder 159 calculates a sum of output values of the adders 155 to 157 and then output the sum. The adder 160 adds output values of the adders 158 and 159 and output a result thereof. Accordingly, a final output of the adder 150 is a total sum of all the products generated by the multipliers 141 to 147 which is equivalent to y(n) in the formula (3). The delayers in the adder 150 serve to add a buffer of one clock cycle between two consecutive stages of the adders.

The adder 150 of FIG. 1 is merely an example. In another embodiment, the architecture of the adder 150 may be changed as long as the adder 150 can output the total sum of all the products generated by the multipliers 141 to 147.

In view of Table 1, each of the adders 121 to 126 performs four addition operations, and the adder 127 performs two addition operations. Each of the multipliers 141 to 146 performs four multiplication operations, and the multiplier 147 performs two multiplication operations. Accordingly, in comparison with a general non-parallel FIR filter, the FIR filter 100 is capable of achieving almost four times the throughput. With the same demand for the throughput, the operation frequency may be reduced in order to reduce requirements for the power consumption. For example, because the FIR filter 100 adopting the 4-way parallel architecture only requires a quarter of the operation frequency, the power consumption may be reduced significantly.

The number of the coefficients of the FIR filter 100 of FIG. 1 is an odd number. Persons of ordinary skill in the art should understand that, with a slight modification made to the FIR filter 100, the number of coefficients may be changed to an even number.

The FIR filter 100 of FIG. 1 adopts the 4-way parallel architecture. In another embodiment, the FIR filter 100 may adopt an L-way parallel architecture, in which L is a predetermined integer greater than one. For the FIR filter 100 which adopts the L-way parallel architecture, each of the inputted batches provided by the delay chain 110 includes L input values, such that each of the adders 121 to 127 is capable of performing L addition operations simultaneously at the most and each of the multipliers 141 to 147 is capable of performing L multiplication operations simultaneously at the most.

The FIR filter 100 of FIG. 1 having 51 coefficients is equivalent to the circumstance where N in the formula (3) is equal to 51. In another embodiment, the number N of the coefficients of the FIR filter 100 may be changed. In such embodiment, the number of the delayers in the delay chain 110, the number of the adders 121 to 127, the number of the delayers 131 to 137, the number of the multipliers 141 to 147 and the architecture of the adder 150 may all be adjusted in accordance with different values of N. As a general rule, the number of the delayer in the delay chain 110, the number of the adders 121 to 127, the number of the delayers 131 to 137 and the number of the multipliers 141 to 147 are all proportional to N. Accordingly, the architecture of the FIR filter 100 is capable of adapting any value of N.

The parallel architecture of the FIR filter 100 can increase a number and an area of the hardware. In order to reduce the hardware area, the coefficients h₁ to h₂₆ can be simplified. For instance, assuming that each of the coefficients h₁ to h₂₆ is a predetermined constant of 10-bits, such that each of the multiplication operations performed by the multipliers 141 to 147 requires λ times of shifts and the addition operations, where λ is the number of non-zero bits corresponding to the coefficients, and the maximum number of λ is 10. If each of the coefficients h₁ to h₂₆ can be simplified to include only two or three non-zero bits, the multiplication operations and the corresponding hardware area may then be significantly simplified.

As mentioned above, the coefficients h₁ to h₂₆ in Table 1 are equivalent to the coefficients h(i) in formulas (3) and (4). Hereinafter, h(i) is used to represent the coefficients h₁ to h₂₆. In an embodiment, a formula (5) may be used to calculate one corresponding simplified coefficient ĥ(i) for each original coefficient h(i).

$$\hat{h} ( i ) = {\sum }_{k = 1}^{{λ}_{i}} {c}_{k , i} {2}^{- {g}_{k , i}} \qquad ( 5 )$$

In the formula (5), λᵢ is equal to 2 or 3. c_{k,i} is equal to −1, 0 or 1. g_{k,i} is an integer greater than or equal to 0 and less than the number of bits of the original coefficients h(i). c_{k,i} and g_{k,i} are optimal parameters obtained by searching in the time domain and the frequency domain by using a tap search. The tap search of the present embodiment will be described in details later. Each multiplication operation in Table 1 and the corresponding hardware circuit may be simplified by replacing the corresponding original coefficient h(i) with the corresponding simplified coefficient ĥ(i).

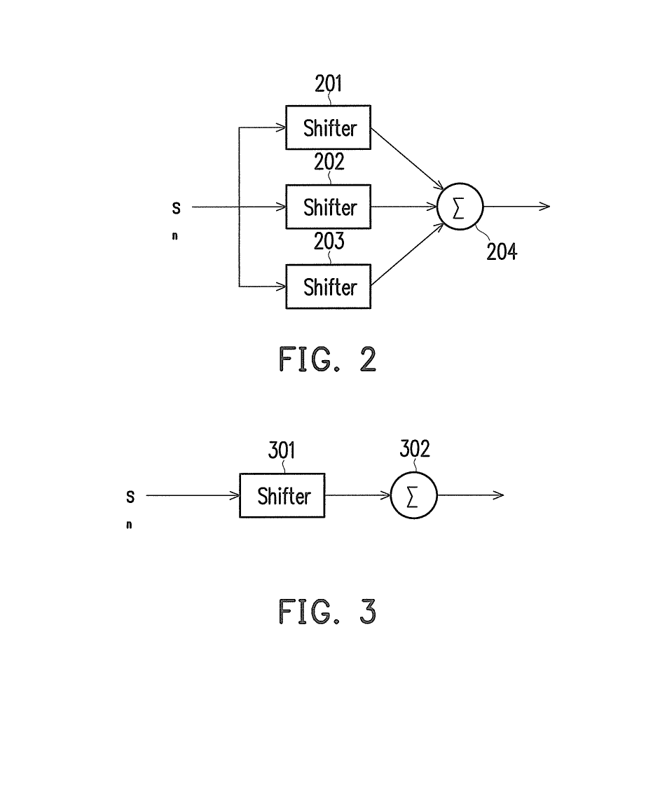

FIG. 2 is a schematic diagram illustrating a part of the multipliers 141 to 147 according to an embodiment of the present disclosure. Herein, the multiplier 141 is taken as an example. For each of the multiplication operations performed by the multiplier 141, the multiplier 141 may include one multiplication circuit as depicted in FIG. 2 for performing the multiplication operation. Each of the remaining multipliers 142 to 147 also includes one multiplication circuit. λᵢ corresponding to the multiplication circuit is equal to 3. Accordingly, the multiplication circuit of FIG. 2 includes three shifters 201 to 203 and one adder 204. The adder 204 is coupled to the shifters 201 to 203.

The shifters 201 to 203 receive the sum sₙ of the corresponding multiplication operation. The shifters 201 to 203 are respectively corresponding to the parameters g_{1,i}, g_{2,i} and g_{3,i} corresponding to the coefficients h(i) of the multiplication circuit. The shifter 201 shifts the sum sₙ for g_{1,i} times and the outputs the shifted sum which is equivalent to the sum sₙ multiplied by 2^{-g}^{_{1,i}}. The shifter 202 shifts the sum sₙ for g_{2,i} times and the outputs the shifted sum which is equivalent to the sum sₙ multiplied by 2^{-g}^{_{2,i}}. The shifter 203 shifts the sum sₙ for g_{3,i} times and the outputs the shifted sum which is equivalent to the sum sₙ multiplied by 2^{-g}^{_{3,i}}. The adder 204 adds and/or subtracts outputs of the shifters 201 to 203 according to the parameters c_{k,i} of the corresponding coefficients h(i), so as to generate the simplified coefficient ĥ(i) in the formula (5).

In another embodiment, if λᵢ corresponding to the multiplication circuit of FIG. 2 is equal to 2, the shifter 203 may then be omitted.

FIG. 3 is a schematic diagram illustrating a part of the multipliers 141 to 147 according to another embodiment of the present disclosure. Herein, the multiplier 141 is taken as an example. For each of the multiplication operations performed by the multiplier 141, the multiplier 141 may include one multiplication circuit as depicted in FIG. 3. Each of the remaining multipliers 142 to 147 also includes one multiplication circuit. The multiplication circuit of FIG. 3 includes a shifter 301 and an adder 302. The adder 302 is coupled to the shifter 301.

The shifter 301 receives the sum sₙ of the multiplication operation corresponding to the multiplication circuit. In the k^{th} cycle of a clock signal, the sifter 301 shifts the sum sₙ for g_{k,i} times and outputs the shifted sum which is equivalent to the sum sₙ multiplied by 2^{-g}^{_{k,i}}. The adder 302 is capable of accumulating the k outputs of the shifter 301, so as to generate the simplified coefficient ĥ(i) in formula (5).

Description regarding how to search the optimal parameters c_{k,i} and g_{k,i} by using the tap search in an embodiment of the present disclosure is provided as follows. First of all, the corresponding parameters c_{k,i} and g_{k,i} for each of the original coefficients h(i) are searched in the time domain according to a formula (6).

$${e}_{q} ( G ) = {\sum }_{i = 0}^{( N - 1 ) / 2} {[ h ( i ) - \frac{Q ( G \cdot \hat{h} ( i )}{G} ]}^{2} \qquad ( 6 )$$

In the formula (6), N is the number of coefficients of the FIR filter 100 of the present embodiment, and N of the present embodiment is an odd number. G is a parameter having a plurality of possible values. For example, an arithmetic sequence may be defined, and G may be any one value in the arithmetic sequence. For instance, the range of 0.5 to 1 may be divided into 500 equal parts, and the length of each of the equal parts is (1−0.5)/500=0.001. The aforesaid arithmetic sequence may be the 501 endpoints of the 500 equal parts, in which 0.5 and 1 are two endpoints among the 501 endpoints, and G may be any one of the 501 endpoints. Q( ) is a quantization function mapping one real number to the one element in a domain D which is closest to that real number. A formula (7) below is a definition of the domain D.

$$D = \{ β ∈ R \vert β = {\sum }_{k = 1}^{λ} {c}_{k} {2}^{- {g}_{k}} \} \qquad ( 7 )$$

β in the formula (7) represents the elements of the domain D, and R represents the set of all real numbers. β in the formula (7) has a definition similar to that of the simplified coefficient ĥ(i) in the formula (5), such that λ in formula (7) is analogous to λᵢ in the formula (5). λ is equal to 2 or 3. cₖ is equal to −1, 0 or 1. gₖ is an integer greater than or equal to 0 and less than the number of bits of the original coefficients h(i)). The domain D is the set composed of all real numbers that can be expressed in the manner of the formula

$${\sum }_{k = 1}^{λ} {c}_{k} {2}^{- {g}_{k}} .$$

The formula (6) is equivalent to a calculation of an error value e_{q}(G) between all the original coefficients h(i) and all the simplified coefficients ĥ(i). The definition of the simplified coefficient ĥ(i) in the formula (6) is identical to that in the formula (5). For each simplified coefficient ĥ(i), each of the corresponding parameters c_{k,i} and g_{k,i} has a plurality of possible values. The parameter G also has a plurality of possible values. In the formula (6), each combination of the possible values of (N−1)/2+1 parameters c_{k,i}, (N−1)/2+1 parameters g_{k,i} and one parameter G may be used for calculating one corresponding error value e_{q}(G). By sorting the error values e_{q}(G) obtained from all the combinations, a minimum error value e_{q(min)} among the error values may be obtained, and then a plurality of error values e_{q} less than M*e_{q(min)} may be selected from the error values. The selected error values e_{q} also include the minimum error value e_{q(min)}. M is a predetermined constant and M of the present embodiment is equal to 5. In another embodiment, M may be any integer greater than one.

The formula (6) shows that each selected error value e_{q} is corresponding to a plurality of parameters c_{k,i} and a plurality of parameters g_{k,i}. A frequency response of the FIR filter 100 may be calculated by replacing the original coefficients h(i) with the simplified coefficients ĥ(i) calculated based on the parameters c_{k,i} and g_{k,i}. Therefore, each selected error value e_{q} is corresponding to one frequency response. The next step is parameters searching in the frequency domain. In other words, the frequency response corresponding to each of the selected error values e_{q} is compared with the original frequency response of the FIR filter 100, such that the frequency response that is most similar to the original frequency response may be found, and the error value e_{q} corresponding to the most similar frequency response may also be found. The parameters c_{k,i} and g_{k,i} corresponding to this most similar error value e_{q} are the optimal parameters adopted in the formula (5).

There are many existing methods for determining whether two frequency responses are similar, and the aforesaid parameters searching in the frequency domain may use any one of those methods. For example, the mean of the corresponding frequency responses for each of the error values e_{q} in the pass band of the FIR filter 100 may be calculated in the frequency domain, and the mean of the original frequency response of the FIR filter 100 in the same pass band may be calculated in the frequency domain. Which one of the frequency responses corresponding to the selected error values e_{q} is most similar to the original frequency response may be decided by comparing the aforesaid means.

The formula (6) is suitable for the circumstance where the number N of the coefficients of the FIR filter 100 is an odd number. If the number N of the coefficients of the FIR filter 100 is an even number, the formula (8) below may be used to replace the formula (6).

$${e}_{q} ( G ) = {\sum }_{i = 0}^{N / 2 - 1} {[ h ( i ) - \frac{Q ( G \cdot \hat{h} ( i )}{G} ]}^{2} \qquad ( 8 )$$

The FIR filter 100 is capable disabling a part of the multiplication operations based on desired applications, so that outputs of the multiplication operation being disabled may be zero. Accordingly, the same FIR filter may be used to satisfy a variety of spectrum masks while reducing unnecessary power consumption.

More specifically, the coefficients h(i) of the FIR filter 100 may be numbered 0 to N−1 (i.e., h(0) to h(N−1)). The coefficients h(i) may be divided into two sets S1 and S2. The set S1 includes the j^{th} coefficient to the (N−1−j)^{th} coefficient in the coefficients h(i) (i.e., h(j) to h(N−1−j)), and j is a positive integer less than N/2. The other set S2 includes the remaining coefficients h(i). The FIR filter 100 is capable of disabling the multiplication operations corresponding to the coefficients in the set S2, so that outputs of the disabled multiplication operations are zero. As described in the embodiments of FIG. 2 and FIG. 3, each of the multiplication operations includes one corresponding multiplication circuit. Therefore, disabling the multiplication operation is to disable the corresponding multiplication circuit.

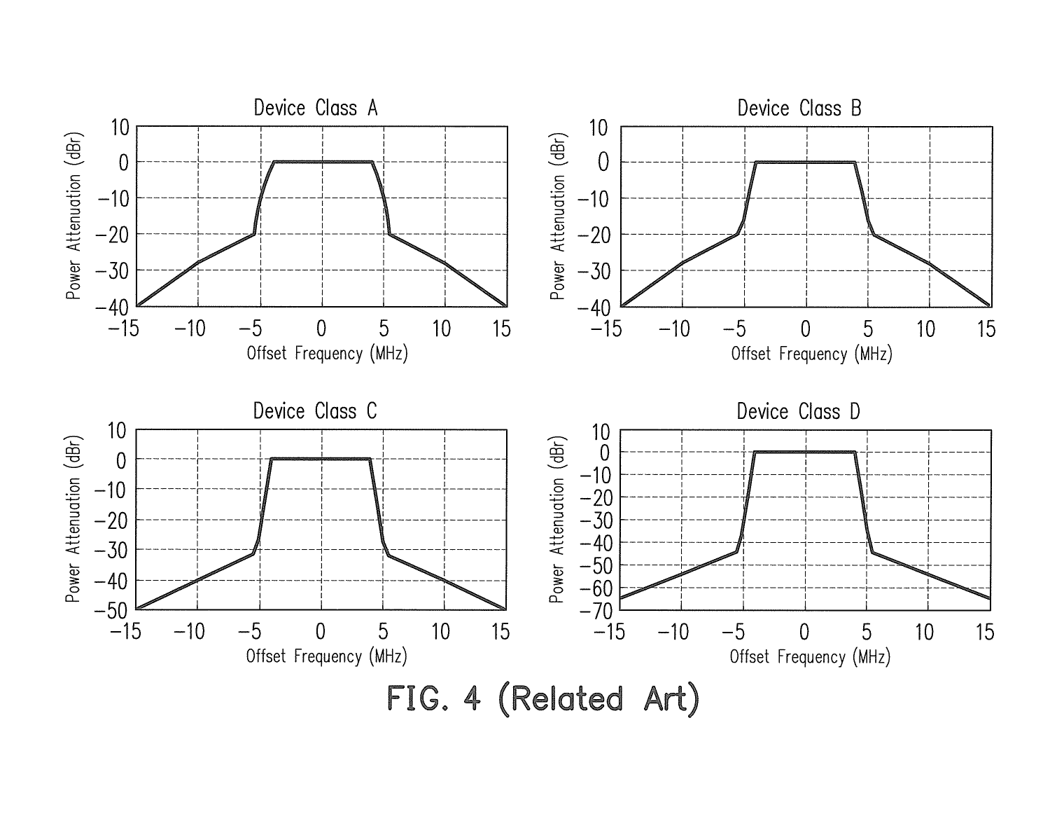

For instance, each device class of the DSRC (Dedicated Short Range Communications) system of IEEE (Institute of Electrical and Electronics Engineers) 802.11p communication standard has a corresponding transmission spectrum mask. FIG. 4 illustrates transmission spectrum masks of device classes A to D operated under the 5.9 DSRC spectrum, in which each mask diagram has a horizontal axis representing a power attenuation and a vertical axis representing an offset frequency.

Take the FIR filter 100 in one embodiment of the present disclosure as an example, it is assumed that the number N of the coefficients h(i) is 71. As shown in FIG. 4, the device class A and the device class B need to suppress the power outside the operation band to approximately −20 dBr. In this case, the set S1 only needs to include the 23 coefficients at the middle of h(i) (i.e., h(24) to h(46)). Considering that the coefficients h(i) of the FIR filter 100 are symmetric, only the 12 multiplication operations corresponding to the coefficients h(24) to h(46) are required. The multiplication circuits corresponding to the remaining multiplication operations may be disabled.

Similarly, the device class C needs to suppress the power outside the operation band to approximately −30 dBr. In this case, the set S1 needs to include the 39 coefficients at the middle of h(i) (i.e., h(16) to h (54)), which also means that only the 20 multiplication operations corresponding to h(16) to h(54) are required. The multiplication circuits corresponding to the remaining multiplication operations may be disabled.

The device class D needs to suppress the power outside the operation band to approximately −45 dBr. In this case, all of the coefficients are to be used and all of the 36 multiplication operations are required. Each of the multiplication circuits is enabled.

The numbers of the multiplication circuits used by the device classes A and B are only one third of the number of the multiplication circuits used by the device class D. That is to say, two-thirds of the multiplication circuits of the FIR filter 100 may be disabled for the device classes A and B, so as to avoid unnecessary power consumption. The FIR filter 100 may be designed based on a windowing algorithm to benefit from the aforesaid operation of disabling a part of the multiplication circuits.

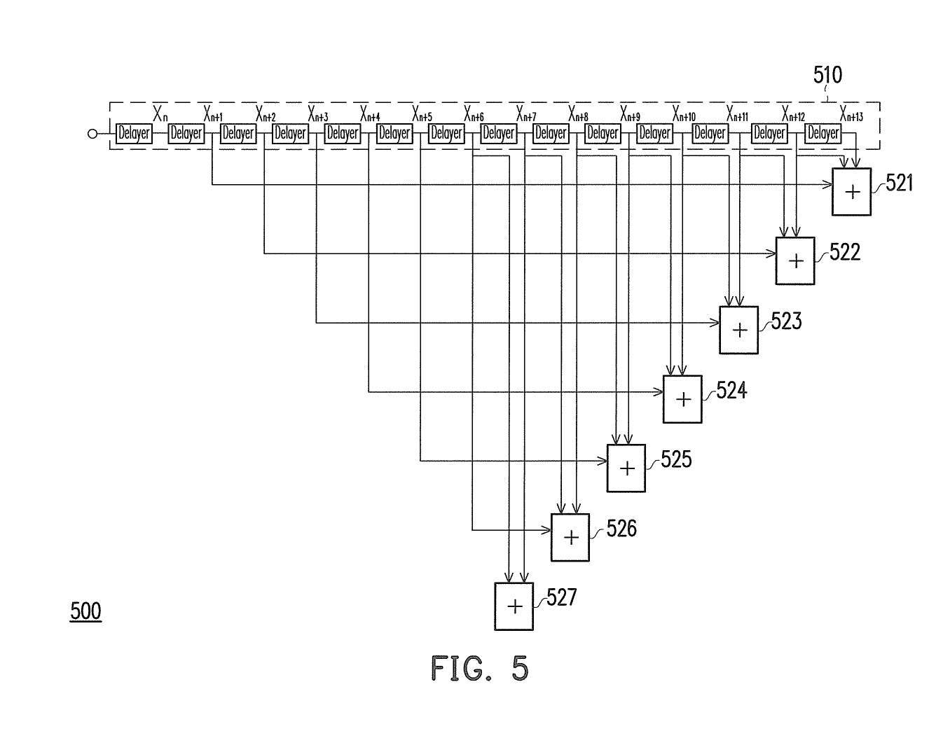

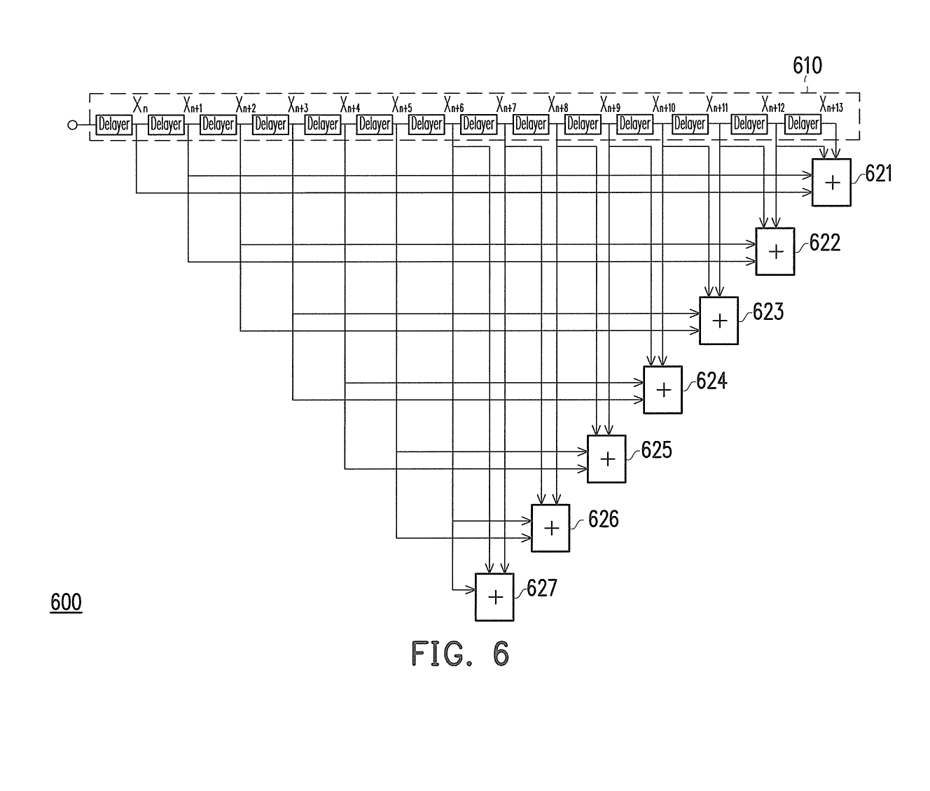

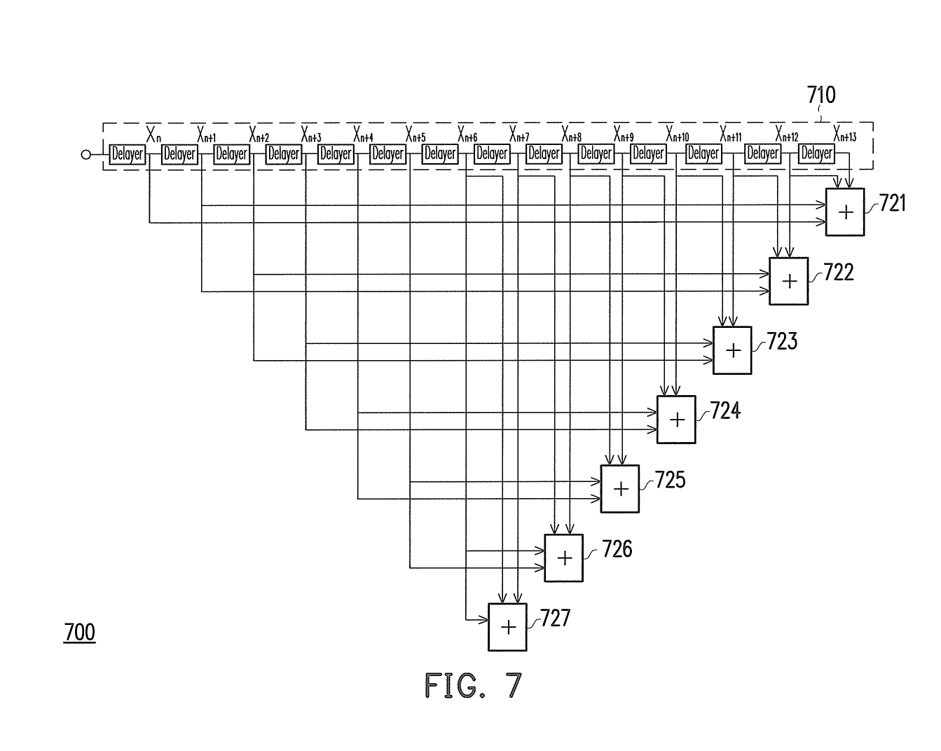

In another embodiment of the present disclosure, a combination of multiple parallel FIR filters similar to the FIR filter 100 may be used to achieve higher degree of parallelism. For example, four FIR filters (the FIR filter 100 of FIG. 1, the FIR filter 500 of FIG. 5, the FIR filter 600 of FIG. 6 and the FIR filter 700 of FIG. 7) may be grouped to form a FIR filter with higher degree of parallelism.

FIG. 5 is a schematic diagram illustrating the FIR filter 500 of the present embodiment. In FIG. 5, only the FIR filter 500, a delay chain 510 and adders 521 to 527 are illustrated. The remaining parts of the FIR filter 500 are identical to those in the FIR filter 100 of FIG. 1. FIG. 6 is a schematic diagram illustrating the FIR filter 600 of the present embodiment. In FIG. 6, only the FIR filter 600, a delay chain 610 and adders 621 to 627 are illustrated. The remaining parts of the FIR filter 600 are identical to those in the FIR filter 100 of FIG. 1. FIG. 7 is a schematic diagram illustrating the FIR filter 700 of the present embodiment. In FIG. 7, only the FIR filter 700, a delay chain 710 and adders 721 to 727 are illustrated. The remaining parts of the FIR filter 700 are identical to those in the FIR filter 100 of FIG. 1. The adders 521 to 527, 621 to 627 and 721 to 727 are all capable of performing a plurality of addition operations simultaneously. Table 2 below lists the addition operations performed by the adders 521 to 527, 621 to 627 and 721 to 727.

TABLE 2

| | Addition | | Addition | | Addition |
|---|---|---|---|---|---|
| Adders | operations | Adders | operations | Adders | operations |
| 521 | X_{n+13,2} + X_{n+1,4} | 621 | X_{n+13,3} + X_{n,1} | 721 | X_{n+13,4} + X_{n,2} |
| | X_{n+13,3} + X_{n+1,3} | | X_{n+13,4} + X_{n+1,4} | | X_{n+12,1} + X_{n,1} |
| | X_{n+13,4} + X_{n+1,2} | | X_{n+12,1} + X_{n+1,3} | | X_{n+12,2} + X_{n+1,4} |
| | X_{n+12,1} + X_{n+1,1} | | X_{n+12,2} + X_{n+1,2} | | X_{n+12,3} + X_{n+1,3} |
| 522 | X_{n+12,2} + X_{n+2,4} | 622 | X_{n+12,3} + X_{n+1,1} | 722 | X_{n+12,4} + X_{n+1,2} |
| | X_{n+12,3} + X_{n+2,3} | | X_{n+12,4} + X_{n+2,4} | | X_{n+11,1} + X_{n+1,1} |
| | X_{n+12,4} + X_{n+2,2} | | X_{n+11,1} + X_{n+2,3} | | X_{n+11,2} + X_{n+2,4} |
| | X_{n+11,1} + X_{n+2,1} | | X_{n+11,2} + X_{n+2,2} | | X_{n+11,3} + X_{n+2,3} |
| 523 | X_{n+11,2} + X_{n+3,4} | 623 | X_{n+11,3} + X_{n+2,1} | 723 | X_{n+11,4} + X_{n+2,2} |
| | X_{n+11,3} + X_{n+3,3} | | X_{n+11,4} + X_{n+3,4} | | X_{n+10,1} + X_{n+2,1} |
| | X_{n+11,4} + X_{n+3,2} | | X_{n+10,1} + X_{n+3,3} | | X_{n+10,2} + X_{n+3,4} |
| | X_{n+10,1} + X_{n+3,1} | | X_{n+10,2} + X_{n+3,2} | | X_{n+10,3} + X_{n+3,3} |
| 524 | X_{n+10,2} + X_{n+4,4} | 624 | X_{n+10,3} + X_{n+3,1} | 724 | X_{n+10,4} + X_{n+3,2} |
| | X_{n+10,3} + X_{n+4,3} | | X_{n+10,4} + X_{n+4,4} | | X_{n+9,1} + X_{n+3,1} |
| | X_{n+10,4} + X_{n+4,2} | | X_{n+9,1} + X_{n+4,3} | | X_{n+9,2} + X_{n+4,4} |
| | X_{n+9,1} + X_{n+4,1} | | X_{n+9,2} + X_{n+4,2} | | X_{n+9,3} + X_{n+4,3} |
| 525 | X_{n+9,2} + X_{n+5,4} | 625 | X_{n+9,3} + X_{n+4,1} | 725 | X_{n+9,4} + X_{n+4,2} |
| | X_{n+9,3} + X_{n+5,3} | | X_{n+9,4} + X_{n+5,4} | | X_{n+8,1} + X_{n+4,1} |
| | X_{n+9,4} + X_{n+5,2} | | X_{n+8,1} + X_{n+5,3} | | X_{n+8,2} + X_{n+5,4} |
| | X_{n+8,1} + X_{n+5,1} | | X_{n+8,2} + X_{n+5,2} | | X_{n+8,3} + X_{n+5,3} |
| 526 | X_{n+8,2} + X_{n+6,4} | 626 | X_{n+8,3} + X_{n+5,1} | 726 | X_{n+8,4} + X_{n+5,2} |
| | X_{n+8,3} + X_{n+6,3} | | X_{n+8,4} + X_{n+6,4} | | X_{n+7,1} + X_{n+5,1} |
| | X_{n+8,4} + X_{n+6,2} | | X_{n+7,1} + X_{n+6,3} | | X_{n+7,2} + X_{n+6,4} |
| | X_{n+7,1} + X_{n+6,1} | | X_{n+7,2} + X_{n+6,2} | | X_{n+7,3} + X_{n+6,3} |
| 527 | X_{n+7,2} + X_{n+7,4} | 627 | X_{n+7,3} + X_{n+6,1} | 727 | X_{n+7,4} + X_{n+6,2} |
| | X_{n+7,3} + 0 | | X_{n+7,4} + 0 | | X_{n+6,1} + 0 |

Table 1 shows that the FIR filter 100 calculates the convolution of the input values X_{n+1,3} to X_{n+13,1} and the coefficients h₁ to h₅₁. Because the coefficients h₁ to h₅₁ are symmetric, the FIR filter 100 practically only uses the coefficients h₁ to h₂₆. Table 2 shows that the FIR filter 500 calculates the convolution of the input values X_{n+1,4} to X_{n+13,2} and the coefficients h₁ to h₅₁, the FIR filter 600 calculates the convolution of the input values X_{n,1} to X_{n+13,3} and the coefficients h₁ to h₅₁, and the FIR filter 700 calculates the convolution of the input values X_{n,2} to X_{n+13,4} and the coefficients h₁ to h₅₁. In this way, there are four FIR filters calculating four different convolutions simultaneously. The combination of the FIR filters 100, 500, 600 and 700 is capable of performing 16 addition operations and 16 multiplication operations simultaneously in parallel in each clock cycle and thereby increasing the throughput to 16 times the throughput of a general non-parallel FIR filter.

In order to describe the aforesaid parallel FIR filter more clearly, the input values in the input sequence may be consecutively numbered. For example, the batch X₁ includes input values x(1) to x(4), the batch X₂ includes input values x(5) to x(8), and the rest may be deduced by analogy. Table 3 below lists the convolutions calculated in each clock cycle of four clock cycles and the relation between the convolutions and the output values y(n) in the formula (3) under the circumstance where only the FIR filter 100 is used. The other clock cycles may be deduced by analogy. Table 4 below lists the convolutions calculated in each clock cycle of four clock cycles and the relation between the convolutions and the output values y(n) in the formula (3) under the circumstance where the FIR filter composed of the FIR filters 100, 500, 600 and 700 is used. The other clock cycles may be deduced by analogy.

TABLE 3

| Clock cycle | Calculated convolutions |
|---|---|
| T | y(1) = the convolution of the input values x(1) to x(51) |
| | and the coefficients h₁ to h₅₁ |
| T + 1 | y(2) = the convolution of the input values x(2) to x(52) |
| | and the coefficients h₁ to h₅₁ |
| T + 2 | y(3) = the convolution of the input values x(3) to x(53) |
| | and the coefficients h₁ to h₅₁ |
| T + 3 | y(4) = the convolution of the input values x(4) to x(54) |
| | and the coefficients h₁ to h₅₁ |

TABLE 4

| Clock cycle | Calculated convolutions |
|---|---|
| T | y(1) = the convolution of the input values x(1) to x(51) |
| | and the coefficients h₁ to h₅₁ |
| | y(2) = the convolution of the input values x(2) to x(52) |
| | and the coefficients h₁ to h₅₁ |
| | y(3) = the convolution of the input values x(3) to x(53) |
| | and the coefficients h₁ to h₅₁ |
| | y(4) = the convolution of the input values x(4) to x(54) |
| | and the coefficients h₁ to h₅₁ |
| T + 1 | y(5) = the convolution of the input values x(5) to x(55) |
| | and the coefficients h₁ to h₅₁ |
| | y(6) = the convolution of the input values x(6) to x(56) |
| | and the coefficients h₁ to h₅₁ |
| | y(7) = the convolution of the input values x(7) to x(57) |
| | and the coefficients h₁ to h₅₁ |
| | y(8) = the convolution of the input values x(8) to x(58) |
| | and the coefficients h₁ to h₅₁ |
| T + 2 | y(9) = the convolution of the input values x(9) to x(59) |
| | and the coefficients h₁ to h₅₁ |
| | y(10) = the convolution of the input values x(10) to x(60) |
| | and the coefficients h₁ to h₅₁ |
| | y(11) = the convolution of the input values x(11) to x(61) |
| | and the coefficients h₁ to h₅₁ |
| | y(12) = the convolution of the input values x(12) to x(62) |
| | and the coefficients h₁ to h₅₁ |
| T + 3 | y(13) = the convolution of the input values x(13) to x(63) |
| | and the coefficients h₁ to h₅₁ |
| | y(14) = the convolution of the input values x(14) to x(64) |
| | and the coefficients h₁ to h₅₁ |
| | y(15) = the convolution of the input values x(15) to x(65) |
| | and the coefficients h₁ to h₅₁ |
| | y(16) = the convolution of the input values x(16) to x(66) |
| | and the coefficients h₁ to h₅₁ |

In view of Table 3, if only the FIR filter 100 is used, one input value x(n) may be received and one output value y(n) may be calculated in each clock cycle. In view of Table 4, if the combined parallel FIR filter including the FIR filters 100, 500, 600 and 700 is used, each of the FIR filters 100, 500, 600 and 700 may receive one input value x(n) respectively and calculate one output value y(n) respectively in each clock cycle. As such, the entire combined parallel FIR filter is capable of receiving four input values x(n) and calculating four output values y(n) in each clock cycle. In another embodiment, any number of FIR filters may be combined according to the aforesaid rule in order to achieve lower or higher degree of parallelism.

A filtering method is provided according to an embodiment of the present disclosure. The FIR filter 100 of FIG. 1 may also be regarded as a schematic diagram for processing such filtering method. First, the delay chain 110 receives an input sequence including a plurality of input vales from the input terminal 170. Then, in each clock cycle of a plurality of clock cycles, a plurality of addition operations are performed simultaneously in parallel. For example, the adder 127 performs two addition operations simultaneously in parallel in one specific clock cycle, the adder 126 performs four addition operations simultaneously in parallel in a next clock cycle, the adder 125 performs four addition operations simultaneously in parallel in another clock cycle after the next clock cycle, and the rest may be deduced by analogy. In each clock cycle, only one of the adders 121 to 127 is performing the addition operations. Then, in each clock cycle of a plurality of clock cycles, a plurality of multiplication operations are performed simultaneously in parallel. For example, the multiplier 147 performs two multiplication operations simultaneously in parallel in one specific clock cycle, the multiplier 146 performs four multiplication operations simultaneously in parallel in a next clock cycle, the multiplier 145 performs four multiplication operations simultaneously in parallel in another clock cycle after the next clock cycle, and the rest may be deduced by analogy. In each clock cycle, only one of the multipliers 141 to 147 is performing the multiplication operations. Lastly, the adder 150 outputs a total sum of all the products outputted by the multipliers 141 to 147. Technical details regarding the filtering method have been described in the foregoing embodiments, which are not repeated hereinafter. In another embodiment, the filtering method of the present disclosure is capable of increasing the throughput by calculating a plurality of output values y(n) simultaneously in order to increase the throughput, as described in the embodiments of FIG. 5 to FIG. 7.

In summary, the aforesaid FIR filter is capable of reducing the operation frequency of the transmitter of a communication system in order to reduce power consumption. In aforesaid FIR filter, adders and shifters may be used to replace the multipliers, so as to significantly save the hardware area for the multiplication circuits. Aforesaid FIR filter is also capable of dynamically disabling a part of the multiplication circuits in order to reduce power consumption, and one FIR filter is enough to satisfy the demands for a variety of spectrum masks.

It will be apparent to those skilled in the art that various modifications and variations can be made to the disclosed embodiments. It is intended that the specification and examples be considered as exemplary only, with a true scope of the disclosure being indicated by the following claims and their equivalents

What is claimed is:

1. A finite impulse response filter, receiving an input sequence, the input sequence comprising a plurality of input values, and the finite impulse response filter comprising:
at least one first adder, each of the at least one first adder performing a plurality of addition operations simultaneously in parallel, and each of the addition operations outputting a sum of two of the input values;
at least one multiplier, coupled to the at least one first adder, each of the at least one multiplier performing a plurality of multiplication operations simultaneously in parallel, and each of the multiplication operations outputting a product of one of the sums and one of a plurality of coefficients of the finite impulse response filter; and
a second adder, coupled to the at least one multiplier, and outputting a total sum of the products.

2. The finite impulse response filter of claim 1, further comprising:
a delay chain, coupled to the at least one first adder, receiving the input sequence, and grouping the input values into a plurality of batches according to an order of the input values in the input sequence, wherein each of the batches comprises L input values, L is an integer greater than one, and the at least one first adder obtains the input values from the batches.

3. The finite impulse response filter of claim 2, wherein L is a maximum number of the addition operations simultaneously performed by each of the at least one first adder and L is also a maximum number of the multiplication operations simultaneously performed by each of the at least one multiplier.

4. The finite impulse response filter of claim 2, wherein the delay chain comprises:
at least one delayer coupled in series, wherein the first delayer receives the batches one by one directly from the input sequence, each of the remaining delayers receives the batches one by one from the previous delayer, and each of the at least one delayer delays the received batches for a predetermined time and then outputs the delayed batches.

5. The finite impulse response filter of claim 1, wherein for each of the addition operations, the two of the input values for generating the sum are respectively located before a midpoint of the input sequence and after the midpoint, and locations of the two of the input values in the input sequence are symmetric with respect to the midpoint.

6. The finite impulse response filter of claim 1, wherein each of the at least one first adder uses two groups of consecutive input values in the input values to perform the addition operations of the at least one first adder.

7. The filtering method of claim 1, wherein a number of the coefficients is N, the coefficients are numbered 0 to N−1, N is a positive integer, the coefficients are grouped into a first set and a second set, the first set comprises the j^{th} coefficient to the (N−1−j)^{th} coefficient in the coefficients, the second set comprises the remaining coefficients, j is a positive integer less than N/2, and the finite impulse response filter disables the multiplication operations corresponding to the coefficients in the second set so that outputs of the disabled multiplication operations are zero.

8. The finite impulse response filter of claim 1, wherein the coefficient in each of the multiplication operations is simplified to be
$${\sum }_{k = 1}^{λ} {c}_{k} {2}^{- {g}_{k}} ,$$
λ is equal to 2 or 3, cₖ is equal to −1, 0 or 1, and gₖ is an integer greater than or equal to 0 and less than a number of bits of the coefficient.

9. The finite impulse response filter of claim 8, wherein cₖ and gₖ are obtained by searching in a time domain and a frequency domain by using a tap search.

10. The finite impulse response filter of claim 8, wherein for each of the multiplication operations, each of the at least one multiplier comprises:
a plurality of shifters, each of the shifters corresponding to one said gₖ, and shifting the sum corresponding to the multiplication operation for gₖ times and then outputting the shifted sum which is equivalent to the sum multiplied by 2^{-g}^{ₖ}; and
a third adder, coupled to the shifters, and adding and/or subtracting outputs of the shifters according to said cₖ, so as to generate the simplified coefficient.

11. The finite impulse response filter of claim 8, wherein for each of the multiplication operations, each of the at least one multiplier comprises:
a shifter, shifting the sum for gₖ times and then outputting the shifted sum which is equivalent to the sum multiplied by 2^{-g}^{ₖ} in a k^{th} cycle of a clock signal; and
a third adder, coupled to the shifter, accumulating k outputs of the shifter, so as to generate the simplified coefficient.

12. A filtering method, comprising:
receiving an input sequence, wherein the input sequence comprises a plurality of input values;
in each clock cycle of a plurality of clock cycles, performing a plurality of addition operations simultaneously in parallel, wherein each of the addition operations outputs a sum of two of the input values;
in each of the clock cycles, performing a plurality of multiplication operations simultaneously in parallel, wherein each of the multiplication operations outputs a product of one of the sums and one of a plurality of coefficients; and
outputting a total sum of the products.

13. The filtering method of claim 12, further comprising:
grouping the input values into a plurality of batches according to an order of the input values in the input sequence, wherein each of the batches comprises L input values, L is an integer greater than one, and the addition operations obtain the input values from the batches.

14. The filtering method of claim 13, wherein L is a maximum number of the addition operations simultaneously performed in each of the clock cycles and L is also a maximum number of the multiplication operations simultaneously performed in each of the clock cycles.

15. The filtering method of claim 12, wherein for each of the addition operations, the two of the input values for generating the sum are respectively located before a midpoint of the input sequence and after the midpoint, and locations of the two of the input values in the input sequence are symmetric with respect to the midpoint.

16. The filtering method of claim 12, further comprising:
in each of the clock cycles, performing the addition operations by using two groups of consecutive input values in the input values.

17. The filtering method of claim 12, wherein a number of the coefficients is N, the coefficients are numbered 0 to N−1, N is a positive integer, the coefficients are grouped into a first set and a second set, the first set comprises the j^{th} coefficient to the (N−1−j)^{th} coefficient in the coefficients, and the second set comprises the remaining coefficients, j is a positive integer less than N/2, and the filtering method further comprises:
disabling the multiplication operations corresponding to the coefficients in the second set so that outputs of the disabled multiplication operations are zero.

18. The filtering method of claim 12, wherein the coefficient in each of the multiplication operations is simplified to be
$${\sum }_{k = 1}^{λ} {c}_{k} {2}^{- {g}_{k}} ,$$
λ is equal to 2 or 3, cₖ is equal to −1, 0 or 1, and gₖ is an integer greater than or equal to 0 and less than a number of bits of the coefficient.

19. The filtering method of claim 18, wherein cₖ and gₖ are obtained by searching in a time domain and a frequency domain by using a tap search.
